(19) United States
(12) Patent Application Publication
(10) Pub. No.: US 2026/0095699 A1
(43) Pub. Date: Apr. 2, 2026

(54) ELECTROACOUSTIC TRANSDUCER WITH ELECTRICAL CONNECTIONS ON A MEMBRANE

(71) Applicant: STMicroelectronics International N.V., Geneva (CH)

(72) Inventors: Fabrizio CERINI, Magenta (IT); Federico CUNEO, Agrate Brianza (IT)

(73) Assignee: STMicroelectronics International N.V., Geneva (CH)

(21) Appl. No.: 19/341,483

(22) Filed: Sep. 26, 2025

(30) Foreign Application Priority Data
Sep. 30, 2024 (IT) 102024000021567

(51) Int. Cl. H04R 7/06; B81B 3/00; B81C 1/00; H04R 7/18; H04R 17/00; H04R 31/00

(52) U.S. Cl. CPC H04R 7/06; B81B 3/007; B81C 1/00658; H04R 7/18; H04R 17/00; H04R 31/003; H04R 31/006; B81B 2201/0257; B81B 2203/0118; B81B 2203/0307; B81B 2203/04; H04R 2201/003; H04R 2400/11

(57) ABSTRACT

A microelectromechanical electroacoustic transducer includes: a supporting frame containing semiconductor material; a membrane made of semiconductor material connected to the supporting frame along a perimeter; a central piezoelectric transducer on a central portion of the membrane; elastic elements, defined by respective portions of the membrane, the central portion of the membrane being connected to the supporting frame by elastic elements; and metal lines extending on respective elastic elements and on the central portion of the membrane from the elastic elements to the central piezoelectric transducer. The metal lines are made of a metal immune to oxidation by exposure to the atmosphere.

### PRIORITY CLAIM

This application claims the priority benefit of Italian Application for Patent No. 102024000021567 filed on Sep. 30, 2024, the content of which is hereby incorporated by reference in its entirety to the maximum extent allowable by law.

### TECHNICAL FIELD

This disclosure relates to an electroacoustic transducer with electrical connections on a membrane.

### BACKGROUND

As is known, users of the vast majority of mobile and stationary processing and communication devices, such as smartphones, tablets, portable and desktop computers, benefit from the use of headphones and earphones, which are by now extremely widespread. This spread, together with the fact that in many cases headphones and earphones are worn continuously for long periods of time, brings with it the need to provide comfortable and practical devices, without sacrificing the quality of audio reproduction. There is therefore an important push towards the manufacture of miniaturized electroacoustic transducers, such as speakers and microphones. Other miniaturized electroacoustic transducers towards which there is growing interest are used for example in probes for ultrasound inspection and, in general, in ultrasound imaging (Piezoelectric Micromachined Ultrasonic Transducer (PMUT)).

However, the solutions currently available are not entirely satisfactory and do not represent a valid compromise between dimensions, performance in terms of high Sound Pressure Level (SPL—for transmitters) or sensitivity (for receivers) and costs.

A first type of electroacoustic transducer, in particular a speaker, utilizes traditional electromagnetic actuation and is capable of ensuring high reproduction quality. However, electromagnetic actuation speakers are not suitable for being miniaturized beyond a certain limit.

Other solutions based on Micro-Electro-Mechanical-Systems (MEMS) technology allow better miniaturization levels to be obtained, but costs and/or performance are not yet suitable enough to replace the electrodynamic speakers.

For example, hybrid devices are known wherein a microelectromechanical actuator, often of the piezoelectric type, is coupled to a polymeric membrane, which is caused to vibrate. The polymeric membrane has the advantage of high flexibility (low Young's modulus), which allows a good response, but has critical issues from the point of view of processing and costs. In fact, the membrane is applied to the portion of the device that houses the actuator only in the back-end step, i.e. in dedicated processing steps, subsequent to the manufacture of the same actuator. Furthermore, hybrid micro-speakers are not suitable for being assembled on boards by using Surface Mount Technology (SMT), because the membrane is not capable of withstanding soldering temperatures.

Other devices made entirely by using MEMS technology meet the miniaturization and cost requirements, but do not achieve sufficient performance in terms of response dynamics and bandwidth.

In particular, some micro-speakers comprise a semiconductor membrane connected to a supporting frame along its perimeter. The criticality of these devices lies mainly in the poor flexibility of the membrane. In fact, to obtain a suitable sound pressure level, the area reduction of the membrane due to miniaturization should be compensated by a greater displacement (the sound pressure is in fact, as a first approximation, proportional to the product A*d, where A is the area of the membrane and d is the displacement). However, the stiffness of the semiconductor material does not allow sufficient displacement, especially at low frequencies.

In other MEMS micro-speakers, the membrane is discontinuous in the inner portion precisely to have greater flexibility and allow greater displacement. Rather than a real membrane, the transducer comprises a plurality of cantilever structures, each of which defines a segment of a polygon or a sector of a circle and extends from a supporting frame. The vertices of the segments or sectors are adjacent to each other at the center of the transducer, without however being joined. Greater response dynamics may thus be obtained, which, however, are not constant over the audio bandwidth. A misalignment in the out-of-plane direction of the cantilever structures, again especially at low frequencies and at resonance, may in fact cause uncontrolled gaps between adjacent sectors, introducing vents in the membrane that may compromise the performance (acoustic short circuit), especially at low frequencies. Furthermore, the quality of the response of MEMS micro-speakers of this type is greatly influenced by process variations, since even small differences in the cantilever structures may cause non-uniform movements and asymmetry in the sound emission, affecting the Total Harmonic Distortion (THD). For example, the devices may simply be affected by the position in which they are formed on the semiconductor wafer. In particular, some characteristics such as zero-time deflection due to residual stresses of the materials may vary between devices that are located closer to the center or the periphery of the wafer.

There is accordingly a need to provide an electroacoustic transducer that allows the limitations described to be overcome or at least mitigated.

### SUMMARY

A microelectromechanical electroacoustic transducer includes a supporting frame that contains semiconductor material, a membrane made of semiconductor material connected to the supporting frame along a perimeter, a central piezoelectric transducer on a central portion of the membrane, elastic elements that are defined by respective portions of the membrane where the central portion of the membrane is connected to the supporting frame by the elastic elements, and metal lines extending on respective elastic elements and on the central portion of the membrane from the elastic elements to the central piezoelectric transducer.

The membrane may be divided into a plurality of sectors delimited by radial slits that extend in a radial direction from respective vertices of the membrane towards the central portion, where the radial slits define cantilever elements in a peripheral portion of the membrane and tabs in the central portion of the membrane, and where each elastic element may include an outer anchor, an inner anchor, outer arms and inner arms, with the outer anchor being attached to a respective cantilever element and the inner anchor being attached to a respective tab.

The metal lines may be made of a metal immune to oxidation by exposure to the atmosphere.

The metal lines may be made of gold or platinum.

The metal lines may be free of coating and may be exposed on the membrane and on the elastic elements.

The membrane may have an N-fold rotational symmetry, where N is an integer.

The supporting frame may have a cavity open on one side and closed on an opposite side by the membrane and the metal lines may extend on a face of the membrane opposite to the cavity.

The membrane may be divided into sectors by radial slits extending from a periphery of the membrane into the central portion.

Each sector may include a respective one of the elastic elements.

Each elastic element may include an outer anchor that is directly or indirectly connected to the supporting frame, an inner anchor that is connected to the central portion of the membrane, outer arms extending in opposite directions from the outer anchor and inner arms extending in opposite directions from the inner anchor.

In each elastic element the outer arms and the inner arms may be parallel to each other and may be connected to each other, to the outer anchor and to the inner anchor so as to form a slot.

The central piezoelectric transducer may include a bottom electrode, a piezoelectric body on the bottom electrode and a top electrode on the piezoelectric body and the metal lines may include a first metal line connecting the top electrode to a first pad on the supporting frame through the respective sector of the membrane.

The metal lines may include a second metal line connecting the bottom electrode to a second pad on the supporting frame through the respective sector of the membrane.

The sectors of the membrane accommodating the first metal line and the second metal line may be rotated by 90 degrees with respect to each other.

The metal lines may include dummy metal lines in sectors of the membrane opposite to the sectors accommodating the first metal line and the second metal line, where the dummy metal lines may extend at least on the elastic element of the respective sector of the membrane and up to the central piezoelectric actuator and where the dummy metal lines may be electrically insulated from the central piezoelectric actuator.

The elastic elements of each sector of the membrane may be symmetrical with respect to a bisector of the respective sector.

Each elastic element may be symmetrical with respect to the bisector of the respective sector.

The transducer may include a peripheral piezoelectric transducer, where the membrane has a peripheral portion and a central portion, in the peripheral portion of the membrane the radial slits define a cantilever element of substantially trapezoidal shape in each sector, in the central portion of the membrane the radial slits define a tab in each sector, the cantilever element and the tab of each sector of the membrane are coupled to each other by the respective elastic element, the peripheral piezoelectric transducer may include a plurality of peripheral actuator portions where each is arranged on the cantilever element of a respective sector of the membrane and extends beyond the perimeter of the membrane on the supporting frame with adjacent peripheral actuator portions being connected to each other by bridges extending on the supporting frame around distal ends of respective radial slits, and the central piezoelectric actuator may include central actuator portions extending in a radial direction from an annular actuator region with each on the tab of a respective sector of the membrane.

A method of manufacturing a microelectromechanical electroacoustic transducer includes forming a supporting frame containing semiconductor material having a cavity that is open on one side, forming a membrane of semiconductor material connected to the supporting frame along a perimeter to close the cavity where the membrane includes a peripheral portion and a central portion, forming radial slits extending in a radial direction from respective vertices of the membrane towards the central portion to divide the membrane into a plurality of sectors where the radial slits define cantilever elements in the peripheral portion and tabs in the central portion, forming elastic elements from respective portions of the membrane where each elastic element includes an outer anchor attached to a respective cantilever element and an inner anchor attached to a respective tab and outer arms and inner arms connecting the outer anchor to the inner anchor, forming a central piezoelectric transducer on the central portion of the membrane where the central piezoelectric transducer includes a bottom electrode and a piezoelectric body and a top electrode, forming metal lines extending on respective elastic elements and on the central portion of the membrane from the elastic elements to the central piezoelectric transducer where the metal lines are made of a conductive material that is immune to oxidation by exposure to atmosphere, and electrically coupling the metal lines to the central piezoelectric transducer to provide electrical connections thereto.

The conductive material immune to oxidation may include gold or platinum.

Forming the metal lines may include forming the metal lines directly on exposed surfaces of the membrane and the elastic elements without applying a passivation coating.

Forming the central piezoelectric transducer may include depositing a bottom metallization structure on the central portion of the membrane, depositing a piezoelectric material layer on the bottom metallization structure, and depositing a top metallization structure on the piezoelectric material layer.

The piezoelectric material layer may include PZT and the bottom and top metallization structures may include platinum.

The method may further include forming dummy metal lines in sectors of the membrane not occupied by the metal lines where the dummy metal lines are electrically isolated from the central piezoelectric transducer.

Forming the membrane may include forming the membrane with an N-fold rotational symmetry where N is an integer.

### BRIEF DESCRIPTION OF THE DRAWINGS

For a better understanding of this disclosure, preferred embodiments are provided, by way of non-limiting example, with reference to the attached drawings, wherein:

FIG. 1 is a simplified block diagram of a processing and communication device;

FIG. 2 is a top-plan view of an electroacoustic transducer in accordance with an embodiment incorporated into the device of FIG. 1;

FIG. 3 shows the electroacoustic transducer of FIG. 2 with parts removed for clarity;

FIG. 4 shows an enlarged detail of the electroacoustic transducer of FIG. 2;

FIG. 5 is a cross-section through the electroacoustic transducer of FIG. 2, sectioned along line V-V of FIG. 2;

FIG. 6 is a cross-section through the electroacoustic transducer of FIG. 2, sectioned along line VI-VI of FIG. 2;

FIG. 7 shows another enlarged detail of the electroacoustic transducer of FIG. 2;

FIG. 8 shows a further enlarged detail of the electroacoustic transducer of FIG. 2;

FIG. 9 is a top-plan view of an electroacoustic transducer in accordance with a different embodiment usable in the device of FIG. 1;

FIG. 10 is a top-plan view of an electroacoustic transducer in accordance with a further embodiment usable in the device of FIG. 1; and

FIG. 11 is a top-plan view of a portion of an electroacoustic transducer in accordance with a further embodiment usable in the device of FIG. 1.

### DETAILED DESCRIPTION

The following description refers to the arrangement shown in the drawings; consequently, expressions such as “above”, “below”, “upper”, “lower”, “top”, “bottom”, “right”, “left” and the like relate to the accompanying figures and are not to be interpreted in a limiting manner.

For convenience, hereinafter reference will be made to electroacoustic transducers used in micro-speakers. However, this is not to be understood in a limiting sense. Electroacoustic transducers according to this disclosure may be used in different devices, both receivers and transmitters, including microphones and ultrasound probes, and, in general, in the field of ultrasound imaging (Piezoelectric Micromachined Ultrasonic Transducers (PMUT)).

Furthermore, here and below, the term transducer is intended to generically indicate a device that converts a first physical quantity (or form of energy) into a corresponding (different) second physical quantity (or form of energy) or vice versa. In some cases, a transducer may be used bidirectionally to convert the first physical quantity into the second physical quantity or the second physical quantity into the first physical quantity, according to the operating conditions. In particular, it is understood that an electroacoustic transducer is a device that converts acoustic waves into a corresponding electrical signal or, vice versa, converts an electrical signal into corresponding acoustic waves. An electroacoustic transducer may be used bidirectionally both to convert acoustic waves into a corresponding electrical signal and to convert an electrical signal into corresponding acoustic waves (for example in ultrasound probes or in some earphones with active noise cancellation). Furthermore, it is understood that a piezoelectric transducer converts forces or pressures applied to faces of the same transducer into a corresponding electrical signal and converts an electrical signal into corresponding forces or pressures applied by faces of the transducer. The piezoelectric transducers are normally usable bidirectionally.

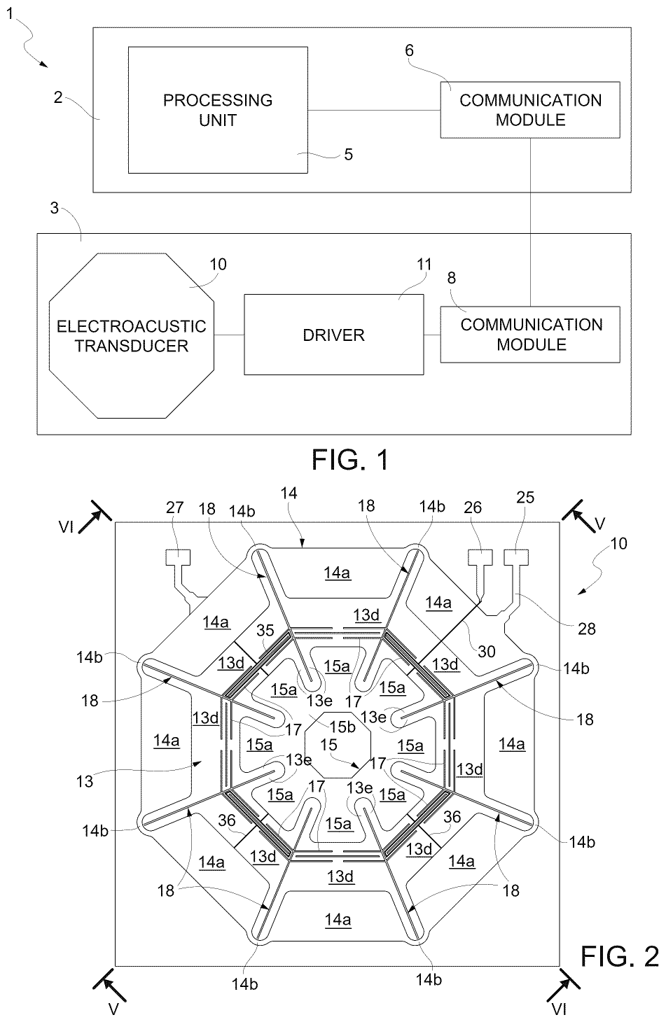

With reference to FIG. 1, an electronic system denoted as a whole by the reference number 1 comprises a processing and communication device 2 coupled in communication with a micro-speaker 3.

The processing and communication device 2 may be any portable or stationary device that supports audio communication with a reproduction peripheral, such as the micro-speaker 3. The processing and communication device 2 may be, but is not limited to, a portable computer, a personal computer, a tablet, a smartphone or a wearable device, for example a smartwatch, and comprises, in particular, a processing unit 5 and a communication module 6, coupled with a corresponding communication module 8 of the micro-speaker 3. The processing and communication device 2 may generally comprise further components not illustrated, such as a display unit, memory units, input and pointing devices, peripherals, a battery, and I/O interfaces.

The micro-speaker 3 comprises, in addition to the communication module 8, an electroacoustic transducer 10 and a driver 11. The driver 11 receives audio signals through the communication module 8 and actuates the electroacoustic transducer 10.

The communication modules 6, 8 of the processing and communication device 2 and of the micro-speaker 3 may be mutually coupled by a wireless or wired connection.

With reference to FIGS. 2-6, the electroacoustic transducer 10 is a piezoelectric-type membrane microelectromechanical transducer and comprises a supporting frame 12, a membrane 13, and piezoelectric transducers, in particular a peripheral piezoelectric actuator 14 and a central piezoelectric actuator 15.

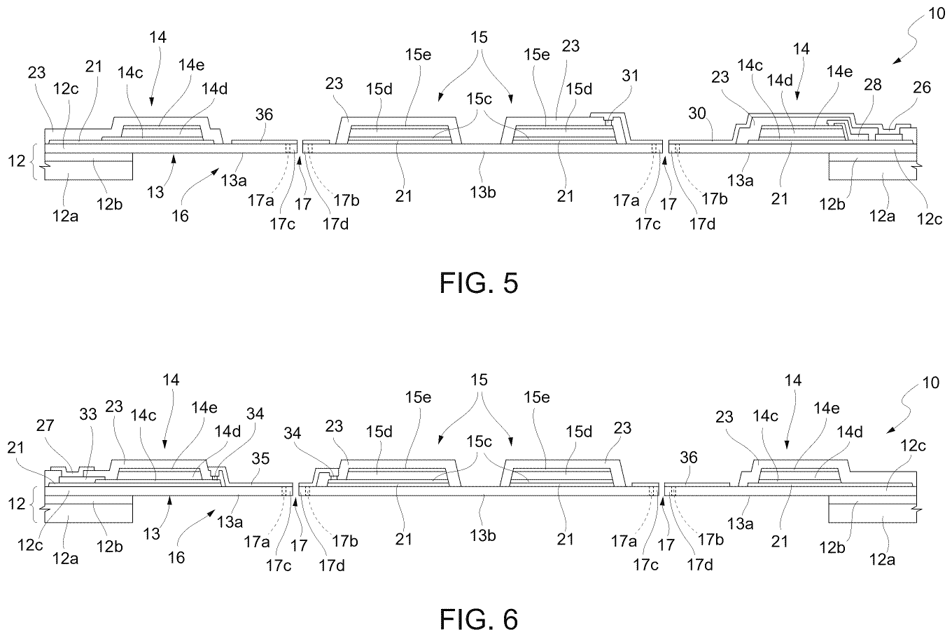

The supporting frame 12 is made of semiconductor material and has a cavity 16 (FIGS. 5 and 6) that is open on one side and closed on the opposite side by the membrane 13. More precisely, the supporting frame 12 may comprise a substrate, for example made of monocrystalline silicon 12a, a dielectric layer 12b and one or more structural layers 12c which may include epitaxial layers, again made of monocrystalline silicon, or layers of polycrystalline silicon grown from a seed in an epitaxial reactor or deposited layers.

The membrane 13, also made of semiconductor material, for example polycrystalline silicon in continuity with the outermost of the structural layers 12c of the supporting frame 12, is connected to the same supporting frame 12 along its perimeter. The membrane 13 may have a thickness of, for example, between 3 μm and 25 μm. In one embodiment, the membrane 13 is polygonal and has an N-fold rotational symmetry with respect to an axis perpendicular to the membrane and passing through the center, with N being an integer. It is understood that a body has an N-fold rotational symmetry with respect to an axis when the body is invariant under rotations of 360°/N around the axis. For example, the membrane 13 may have the shape of a regular octagon. Furthermore, an N-fold rotational symmetry with N even may be advantageous in terms of balancing the stresses (e.g., for the arrangement of dummy connections, as explained in detail below).

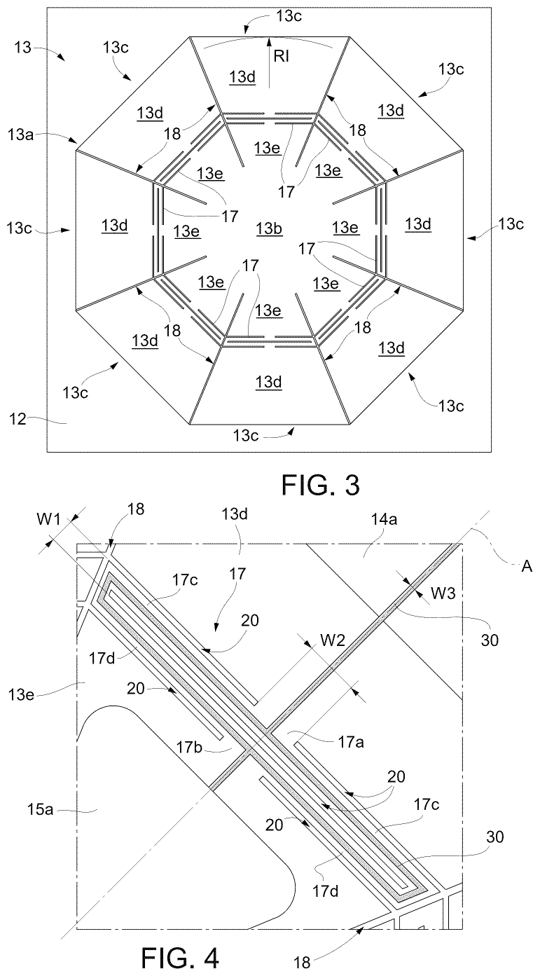

With reference, in particular, to FIG. 3, which for clarity shows only the supporting frame 12 and the membrane 13, the membrane 13 has a peripheral portion 13a, that accommodates the peripheral piezoelectric actuator 14 (FIG. 2), and a central portion 13b, that accommodates the central piezoelectric actuator 15. The peripheral portion 13a and the central portion 13b of the membrane 13 are coupled to each other by connection portions of the same membrane 13 which define elastic elements 17. In a radial direction, the peripheral portion 13a and the central portion 13b may each extend for a distance of, for example, between 30% and 65% of an inscribed radius RI of the membrane 13, which is a regular polygon. In the embodiment of FIGS. 2-6, for example, the peripheral portion 13a and the central portion 13b occupy, respectively, about 40% and about 55% of the inscribed radius RI.

Furthermore, the membrane 13 is divided into a plurality of sectors 13c, delimited by radial slits 18 that extend in a radial direction from respective vertices of the membrane 13 towards the central portion 13b. Outwardly, the radial slits 18 may reach the margin of the membrane 13 or even the supporting frame 12, depending on design preferences; inwardly, however, the radial slits 18 extend for a section of between a quarter and two thirds of the central portion 13b of the membrane 13, here in particular for about one third. In one embodiment, the radial slits 18 all have the same width. Furthermore, the width of the radial slits 18 is less than twice a thickness of a low-frequency viscous boundary layer of air (e.g. 100 Hz), in particular in an operating temperature range of, for example, between −20° C. and +40° C. In one embodiment, the width is less than the thickness of the low-frequency viscous boundary layer of air and is in any case not greater than 10 μm, e.g. 5 μm. Furthermore, a ratio between the width and a thickness of the membrane 13 is not greater than 1.

In the peripheral portion 13a of the membrane 13, the radial slits 18 define cantilever elements 13d of substantially trapezoidal shape, one in each sector 13c. In the central portion 13b of the membrane 13, the radial slits 18 define tabs 13e, one in each sector 13c. In particular, in each sector 13c the cantilever element 13d has a major base connected to the supporting frame 12 and a minor base connected to the corresponding tab 13e of the central portion 13b of the membrane 13 by a respective elastic element 17.

With reference, in particular, to the enlargement of FIG. 4, each elastic element 17 is formed directly by a portion of the membrane 13 and is symmetrical with respect to an axis A that extends along a radial direction of the membrane 13 corresponding to the bisector of the respective sector 13c. The elastic elements 17 are identical to each other and for convenience reference will be made hereinafter to only one of them, being understood that what is described also applies to all the others. The elastic element 17 comprises an outer anchor 17a, an inner anchor 17b, outer arms 17c and inner arms 17d. The outer anchor 17a and the inner anchor 17b are attached respectively to the cantilever element 13d and to the tab 13e of the respective sector 13c of the membrane 13 along the axis A. The outer arms 17c and the inner arms 17d are parallel to each other and are connected to each other, to the outer anchor 17a and to the inner anchor 17b so as to form a slot. In more detail, the outer arms 17c extend perpendicular to the axis A in opposite directions from the outer anchor 17a up to the radial slits 18 that delimit the respective sector 13c. Similarly, the inner arms 17d extend perpendicular to the axis A in opposite directions from the inner anchor 17b up to the radial slits 18 that delimit the respective sector 13c. The outer arms 17c and the inner arms 17d are joined to each other at the respective distal ends, relative to the outer anchor 17a and the inner anchor 17b.

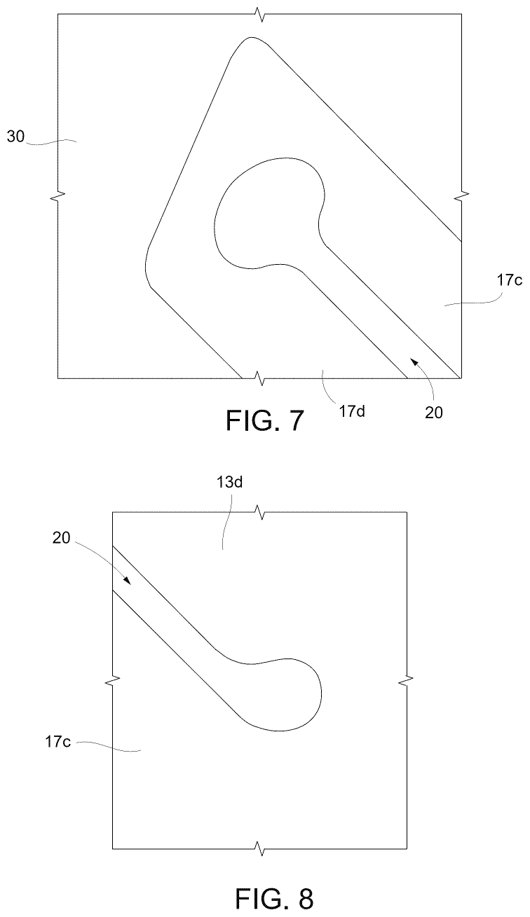

Transverse slits 20, also perpendicular to the axis A, delimit the outer arms 17c and the inner arms 17d and separate them from the cantilever element 13d and the tab 13e of the respective sector 13c of the membrane 13. As shown in the enlargements of FIGS. 7 and 8, the ends of the transverse slits 20 are widened and rounded to avoid stress concentration and prevent the initiation of cracks.

In a direction perpendicular to the transverse slits 20, the outer arms 17c and the inner arms 17d have a width W1 of between 30 μm and 70 μm, for example 50 μm, and a length of, for example, between 500 μm and 1.5 mm. The outer anchor 17a and the inner anchor 17b have a width W2 of between 70 μm and 150 μm, for example 100 km.

The peripheral piezoelectric actuator 14 (FIG. 2) is arranged at the periphery of the membrane 13 and partly overlaps the supporting frame 12. More precisely, the peripheral piezoelectric actuator 14 comprises a plurality of peripheral actuator portions 14a of substantially trapezoidal shape, each arranged on the cantilever element 13d of a respective sector 13c of the membrane 13 and extending beyond the perimeter of the same membrane 13, onto the supporting frame 12. Adjacent peripheral actuator portions 14a are connected to each other by bridges 14b, which have the same structure as the peripheral actuator portions 14a and extend on the supporting frame 12 around distal ends of respective radial slits 18.

The central piezoelectric actuator 15 (FIG. 2) is arranged on the central portion 13b of the membrane 13 and comprises central actuator portions 15a that extend in a radial direction from an annular actuator region 15b and form lobes, each on the tab 13e of a respective sector 13c of the membrane 13.

The peripheral piezoelectric actuator 14 and the central piezoelectric actuator 15 use electrical connections that run partly on the membrane 13, including at least some of the elastic elements 17. The structure of the peripheral piezoelectric actuator 14, the central piezoelectric actuator 15, and the electrical connections, as well as the supporting frame 12 and the membrane 13, is shown in detail in the sections of FIGS. 5 and 6. A dielectric layer 21, for example of silicon oxide, is formed on the outermost of the structural layers 12c and covers the supporting frame 12 and portions of the membrane 13 corresponding to the peripheral piezoelectric actuator 14 and the central piezoelectric actuator 15. The peripheral piezoelectric actuator 14 and the central piezoelectric actuator 15 are formed from the same piezoelectric stack comprising: a bottom metallization structure, for example containing a layer of platinum; a layer of piezoelectric material, for example PZT, on the bottom metallization structure; and a top metallization structure, for example also containing a layer of platinum, on the layer of piezoelectric material. In particular, the peripheral piezoelectric actuator 14 and the central piezoelectric actuator 15 comprise respectively: a bottom peripheral electrode 14c and a bottom central electrode 15c, formed from the bottom metallization structure and arranged on respective portions of the dielectric layer 21; a peripheral piezoelectric body 14d and a central piezoelectric body 15d, formed from the piezoelectric layer and arranged on the bottom peripheral electrode 14c and the bottom central electrode 15c, respectively; and a top peripheral electrode 14e and a top central electrode 15e, formed from the top metallization structure and arranged on the peripheral piezoelectric body 14d and the central piezoelectric body 15d, respectively. The peripheral actuator portions 14a and the bridges 14b connecting them are parts of the peripheral piezoelectric actuator 14 and have the same general structure. A passivation structure 23, for example comprising a layer of silicon nitride and possibly covered by one or more electrically insulating layers, protects the supporting frame 12, the peripheral piezoelectric actuator 14 and the central piezoelectric actuator 15. Outside the peripheral piezoelectric actuator 14 and the central piezoelectric actuator 15, the surface of the membrane 13 opposite to the cavity 16 is substantially exposed.

Pads 25, 26, 27 on the supporting frame 12 (FIG. 2) are accessible for biasing, respectively, the top peripheral electrode 14e, the top central electrode 15e and the bottom peripheral electrode 14c, which is maintained at the same potential as the bottom central electrode 15c as explained below.

The pad 25 is coupled to the top peripheral electrode 14e through a first buried metal line 28, for example made of copper, aluminum or an alloy thereof, which extends on the dielectric layer 21 and is incorporated into the passivation structure 23.

The pad 26 is coupled to the top central electrode 15e (FIG. 5) through a first exposed metal line 30, made of a conductive material that is immune to oxidation by exposure to the atmosphere and does not require passivation, for example gold or platinum. The first exposed metal line 30 extends along an arbitrary path from the pad 26 to the periphery of the membrane 13 and from there in a radial direction along the bisector of one of the sectors 13c. More precisely (FIGS. 2 and 5), the first exposed metal line 30 runs on the passivation structure 23 above the supporting frame 12 and the peripheral piezoelectric actuator 14, then on the exposed part of the cantilever element 13d, on the elastic element 17 and again along the bisector of the affected sector 13c on the tab 13e, up to the corresponding central actuator portion 15a. A radially inner end of the first exposed metal line 30 overlaps an edge of the central actuator portion 15a and is electrically coupled thereto by an interconnect 31, for example made of copper, aluminum or an alloy thereof, through the passivation structure 23. In particular, the first exposed metal line 30 extends symmetrically on the outer arms 17c and on the inner arms 17d of the elastic element 17. In one embodiment, the first exposed metal line 30 is formed directly on the membrane 13, where the piezoelectric actuators 14, 15 are not present, and on the elastic element 17. The first exposed metal line 30 (FIG. 4) has a width W3 smaller than the width W1 of the outer arms 17c and the inner arms 17d, in one embodiment not greater than half the width W1 and for example equal to 20 μm.

The pad 27 (FIG. 6) is coupled to the bottom peripheral electrode 14c through a second buried metal line 33, that extends on the dielectric layer 21 and is incorporated into the passivation structure 23.

The bottom peripheral electrode 14c is coupled to the bottom central electrode 15c and maintained at the same potential through a second exposed metal line 35 that extends along the bisector of another of the sectors 13c of the membrane 13, different from the sector 13c accommodating the first exposed metal line 30. In a non-limiting embodiment, the sector 13c accommodating the second exposed metal line 35 is rotated by 90° with respect to the sector 13c accommodating the first exposed metal line 30. The second exposed metal line 35 has ends overlapping respective extensions of the bottom peripheral electrode 14c and the bottom central electrode 15c and is electrically coupled thereto by interconnects 34 through the passivation structure 23. Furthermore, between the bottom peripheral electrode 14c and the bottom central electrode 15c, the second exposed metal line 35 extends on the cantilever element 13d, the elastic element 17 and the tab 13e of the respective sector 13c of the membrane 13. The second exposed metal line 35 is made of the same material as the first exposed metal line 30 and has the same shape, except for a rotation by 90° and the portion of the first exposed metal line 30 that extends on the peripheral piezoelectric actuator 14 and the supporting frame 12.

In one embodiment, dummy metal lines 36 are formed on sectors 13c of the membrane 13 opposite to those accommodating the first exposed metal line 30 and the second exposed metal line 35. The dummy metal lines 36 extend between the peripheral actuator portions 14a and the central actuator portions 15a and on the elastic elements 17 of the respective sectors 13c of the membrane 13, are made of the same material and have the same shape as the first exposed metal line 30 and the second exposed metal line 35. The dummy metal lines 36 are decoupled from the piezoelectric actuators 14, 15, are floating and have the sole function of mechanically balancing the stresses applied to the membrane 13 by the first exposed metal line 30 and the second exposed metal line 35.

It is understood that the arrangement of the first exposed metal line 30, the second exposed metal line 35 and any dummy metal lines 36 may however be different from what has been described so far.

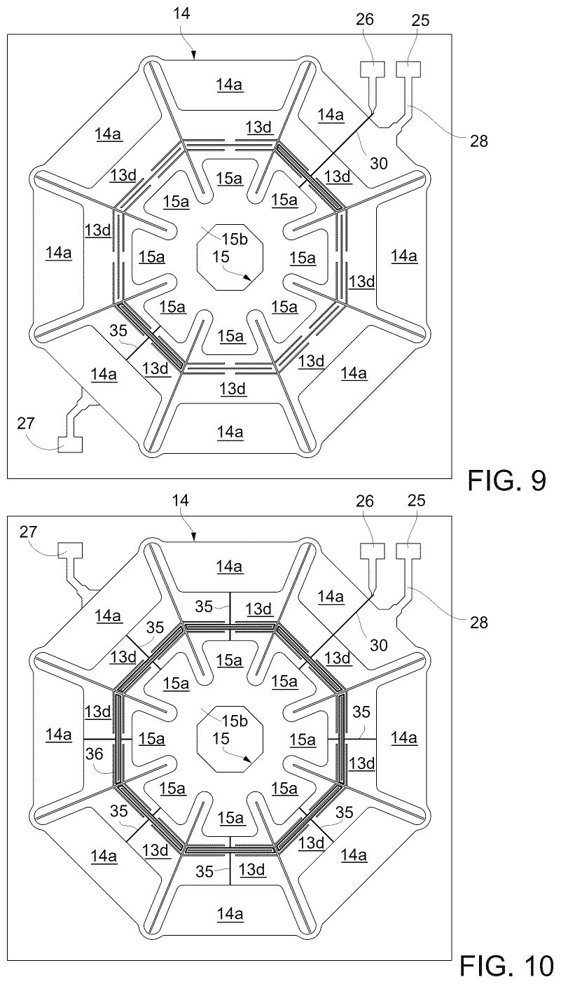

For example, in the embodiment of FIG. 9, the second exposed metal line 35 is opposite to the first exposed metal line 30 and dummy metal lines 36 are not present.

In the embodiment of FIG. 10, dummy metal lines 36 are present in all sectors 13c of the membrane 13 not occupied by the first exposed metal line 30 and the second exposed metal line 35.

In the example described above, the metal lines that connect the central piezoelectric actuator 15 to the pads 26, 27, as well as the dummy metal lines 36 if any, are exposed and free of passivating coating and, in general, of any coating. This is possible because such metal lines are made of a metal immune to oxidation by exposure to the atmosphere, and the absence of coating is particularly advantageous because the effects on the deformability of the membrane 13 and the elastic elements 17 are minimal and, in fact, completely negligible. However, a passivating coating and/or another coating might still be present according to design preferences, for example if the deformability of the membrane and the elastic elements is still considered satisfactory. In this case, the metal lines would not be directly exposed to the atmosphere.

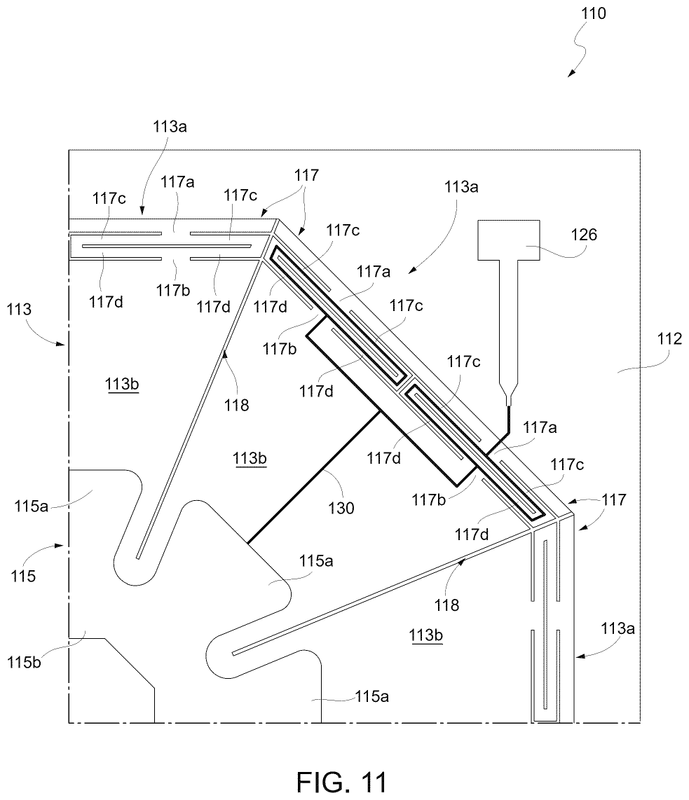

With reference to FIG. 11, an electroacoustic transducer 110 comprises a supporting frame 112, a membrane 113 and a piezoelectric transducer, in particular a piezoelectric actuator 115. The membrane 113, for example made of polycrystalline silicon, has the shape of a regular polygon with an N-fold rotational symmetry, for example an octagon, and is connected to the supporting frame 112 along its perimeter by elastic elements 117. The membrane 113 is divided into a plurality of sectors 113a, delimited by radial slits 118 which extend in a radial direction from respective vertices of the membrane 113 towards the center, up to a certain distance from the center of the same membrane 113. In each sector 113a of the membrane 113, the radial slits 118 delimit tabs 113b coupled to the supporting frame 112 by respective elastic elements 117. More precisely, each tab 113b is coupled to the supporting frame 112 by a plurality of respective elastic elements 117, here two, arranged symmetrically to each other with respect to a bisector of the respective sector 113a. Each elastic element 117 comprises an outer anchor 117a, fixed to the supporting frame 112, an inner anchor 117b fixed to the tab 113b, outer arms 117c and inner arms 117d. The use of multiple elastic elements 117 in each sector 113a allows suitable mobility of the membrane 113 to be ensured, while preventing the elastic elements 117 from being weakened due to the dimensions at the periphery of the tabs 113a.

The piezoelectric actuator 115 is arranged on a central portion of the membrane 113 and comprises portions 115a that extend in a radial direction from an annular actuator region 115b and form lobes, each on the tab 113b of a respective sector 113a of the membrane 113. The piezoelectric actuator 115 has the structure of the actuators 14, 15 already described, with a bottom electrode, a piezoelectric body and a top electrode and is not illustrated in detail.

A pad 126 on the supporting frame 112 is accessible for biasing the piezoelectric actuator 115, in particular the top electrode (not shown). The pad 126 is coupled to the piezoelectric actuator 115 through an exposed metal line 130, made of a conductive material that is immune to oxidation by exposure to the atmosphere and does not require passivation, for example gold or platinum. The exposed metal line 130 extends along an arbitrary path from the pad 126 to the periphery of the membrane 113, over both elastic elements 117 of one of the sectors 113a and from there in a radial direction along the bisector of the same sector 113a. The exposed metal line 130 has a radially inner end coupled to an edge of the respective actuator portion 115a. A further exposed metal line, formed in a similar manner and not illustrated here, may be provided in another sector 113a of the membrane 113 for biasing the bottom electrode of the piezoelectric actuator 115.

The metal lines according to this disclosure allow biasing piezoelectric actuators placed in central portions of membranes connected to the respective supporting frame by elastic elements without appreciably modifying the elastic behavior of the same membranes. More precisely, the use of metals immune to oxidation by exposure to air allows forming exposed metal lines that do not require passivation structures or, if desired according to design preferences, allow providing the metal lines with very thin passivating coatings at least on the membrane and on the elastic elements. In other words, the addition of material on the membrane may be strictly limited to the metal of the same lines, avoiding superfluous structures that would stiffen the membrane and could reduce the dynamics. Alternatively, when the deformability of the membrane and the elastic elements is still considered satisfactory according to design preferences, the metal lines may be provided with thin coatings, in particular passivating coatings, which do not substantially alter the performance of the membrane and the elastic elements.

Furthermore, very high conductivity materials may be used and the dimensions of the metal lines may be correspondingly reduced. In general, this avoids stiffening the membrane, to the advantage of the sound pressure level (for transmitters or actuators) and the sensitivity (for receivers or sensors). Furthermore, the metal lines may be narrow enough to run on the elastic elements, without significantly altering their mechanical properties and without the need for dedicated membrane portions.

Finally, it is clear that modifications and variations may be made to the electroacoustic transducer described, without departing from the scope of this disclosure, as defined in the attached claims.

It is understood, in particular, that electroacoustic transducers according to this disclosure may be effectively used in devices other than micro-speakers, such as, but not limited to, microphones and probes for ultrasound inspection and imaging. While maintaining the same general structure, the electroacoustic transducers may operate either as transmitters (for example micro-speakers) or as receivers (for example microphones) and, in some applications, reversibly both as transmitters and as receivers (for example, in ultrasound imaging probes—PMUT). This is possible because the piezoelectric transducers present on the membrane may operate as actuators in transmitters, converting electrical signals into deformations of the membrane to generate acoustic waves, and as sensors in receivers, converting deformations of the membrane caused by impinging acoustic waves into electrical signals.

1. A microelectromechanical electroacoustic transducer, comprising:
a supporting frame containing semiconductor material;
a membrane made of semiconductor material connected to the supporting frame along a perimeter;
a central piezoelectric transducer on a central portion of the membrane;
elastic elements defined by respective portions of the membrane, wherein the central portion of the membrane is connected to the supporting frame by the elastic elements; and
metal lines extending on respective elastic elements and on the central portion of the membrane from the elastic elements to the central piezoelectric transducer.

2. The microelectromechanical electroacoustic transducer according to claim 1, wherein the membrane is divided into a plurality of sectors delimited by radial slits that extend in a radial direction from respective vertices of the membrane towards the central portion, the radial slits defining cantilever elements in a peripheral portion of the membrane and tabs in the central portion of the membrane, and wherein each elastic element comprises an outer anchor, an inner anchor, outer arms and inner arms, the outer anchor being attached to a respective cantilever element and the inner anchor being attached to a respective tab.

3. The microelectromechanical electroacoustic transducer according to claim 1, wherein the metal lines are made of a metal immune to oxidation by exposure to the atmosphere.

4. The microelectromechanical electroacoustic transducer according to claim 3, wherein the metal lines are made of gold or platinum.

5. The microelectromechanical electroacoustic transducer according to claim 3, wherein the metal lines are free of coating and are exposed on the membrane and on the elastic elements.

6. The microelectromechanical electroacoustic transducer according to claim 1, wherein the membrane has an N-fold rotational symmetry, N being an integer.

7. The microelectromechanical electroacoustic transducer according to claim 1, wherein the supporting frame has a cavity open on one side and closed on an opposite side by the membrane and wherein the metal lines extend on a face of the membrane opposite to the cavity.

8. The microelectromechanical electroacoustic transducer according to claim 1, wherein the membrane is divided into sectors by radial slits extending from a periphery of the membrane into the central portion.

9. The microelectromechanical electroacoustic transducer according to claim 8, wherein each sector comprises a respective one of the elastic elements.

10. The microelectromechanical electroacoustic transducer according to claim 8, wherein each elastic element comprises an outer anchor, directly or indirectly connected to the supporting frame, an inner anchor, connected to the central portion of the membrane, outer arms extending in opposite directions from the outer anchor and inner arms extending in opposite directions from the inner anchor.

11. The microelectromechanical electroacoustic transducer according to claim 10, wherein in each elastic element the outer arms and the inner arms are parallel to each other and are connected to each other, to the outer anchor and to the inner anchor so as to form a slot.

12. The microelectromechanical electroacoustic transducer according to claim 8, wherein the central piezoelectric transducer comprises a bottom electrode, a piezoelectric body on the bottom electrode and a top electrode on the piezoelectric body and wherein the metal lines comprise a first metal line connecting the top electrode to a first pad on the supporting frame through the respective sector of the membrane.

13. The microelectromechanical electroacoustic transducer according to claim 12, wherein the metal lines comprise a second metal line connecting the bottom electrode to a second pad on the supporting frame through the respective sector of the membrane.

14. The microelectromechanical electroacoustic transducer according to claim 13, wherein the sectors of the membrane accommodating the first metal line and the second metal line are rotated by 90° with respect to each other.

15. The microelectromechanical electroacoustic transducer according to claim 14, wherein the metal lines comprise dummy metal lines in sectors of the membrane opposite to the sectors accommodating the first metal line and the second metal line, wherein the dummy metal lines extend at least on the elastic element of the respective sector of the membrane and up to the central piezoelectric actuator and wherein the dummy metal lines are electrically insulated from the central piezoelectric actuator.

16. The microelectromechanical electroacoustic transducer according to claim 8, wherein the elastic elements of each sector of the membrane are symmetrical with respect to a bisector of the respective sector.

17. The microelectromechanical electroacoustic transducer according to claim 16, wherein each elastic element is symmetrical with respect to the bisector of the respective sector.

18. The microelectromechanical electroacoustic transducer according to claim 8, comprising a peripheral piezoelectric transducer, wherein:
the membrane has a peripheral portion and a central portion;
in the peripheral portion of the membrane, the radial slits define a cantilever element of substantially trapezoidal shape in each sector;
in the central portion of the membrane, the radial slits define a tab in each sector;
the cantilever element and the tab of each sector of the membrane are coupled to each other by the respective elastic element;
the peripheral piezoelectric transducer comprises a plurality of peripheral actuator portions, each arranged on the cantilever element of a respective sector of the membrane and extending beyond the perimeter of the membrane, on the supporting frame, adjacent peripheral actuator portions being connected to each other by bridges extending on the supporting frame around distal ends of respective radial slits; and
the central piezoelectric actuator comprises central actuator portions extending in a radial direction from an annular actuator region, each on the tab of a respective sector of the membrane.

19. A method of manufacturing a microelectromechanical electroacoustic transducer, comprising:
forming a supporting frame containing semiconductor material having a cavity that is open on one side;
forming a membrane of semiconductor material connected to the supporting frame along a perimeter to close the cavity, the membrane including a peripheral portion and a central portion;
forming radial slits extending in a radial direction from respective vertices of the membrane towards the central portion to divide the membrane into a plurality of sectors, the radial slits defining cantilever elements in the peripheral portion and tabs in the central portion;
forming elastic elements from respective portions of the membrane, each elastic element comprising an outer anchor attached to a respective cantilever element, an inner anchor attached to a respective tab, and outer arms and inner arms connecting the outer anchor to the inner anchor;
forming a central piezoelectric transducer on the central portion of the membrane, the central piezoelectric transducer comprising a bottom electrode, a piezoelectric body, and a top electrode;
forming metal lines extending on respective elastic elements and on the central portion of the membrane from the elastic elements to the central piezoelectric transducer, the metal lines being made of a conductive material that is immune to oxidation by exposure to atmosphere; and
electrically coupling the metal lines to the central piezoelectric transducer to provide electrical connections thereto.

20. The method according to claim 19, wherein the conductive material immune to oxidation comprises gold or platinum.

21. The method according to claim 19, wherein forming the metal lines comprises forming the metal lines directly on exposed surfaces of the membrane and the elastic elements without applying a passivation coating.

22. The method according to claim 19, wherein forming the central piezoelectric transducer comprises:
depositing a bottom metallization structure on the central portion of the membrane;
depositing a piezoelectric material layer on the bottom metallization structure; and
depositing a top metallization structure on the piezoelectric material layer.

23. The method according to claim 22, wherein the piezoelectric material layer comprises PZT and the bottom and top metallization structures comprise platinum.

24. The method according to claim 19, further comprising forming dummy metal lines in sectors of the membrane not occupied by the metal lines, the dummy metal lines being electrically isolated from the central piezoelectric transducer.

25. The method according to claim 19, wherein forming the membrane comprises forming the membrane with an N-fold rotational symmetry, N being an integer.
